(19) United States
(12) Patent Application Publication
(10) Pub. No.: US 2025/0102535 A1
(43) Pub. Date: Mar. 27, 2025

(54) AIRFLOW SENSOR AND AIRFLOW SENSOR PACKAGING STRUCTURE

(71) Applicant: Memsensing Microsystems (Suzhou, China) Co., Ltd., Suzhou (CN)

(72) Inventors: Yanzi MENG, Suzhou (CN); Senxian KANG, Suzhou (CN)

(73) Assignee: Memsensing Microsystems (Suzhou, China) Co., Ltd., Suzhou (CN)

(21) Appl. No.: 18/895,478

(22) Filed: Sep. 25, 2024

(30) Foreign Application Priority Data
Sep. 26, 2023 (CN) 202311252106.6

(51) Int. Cl. G01P 5/14

(52) U.S. Cl. CPC G01P 5/14

(57) ABSTRACT

Disclosed an airflow sensor and an airflow sensor packaging structure. The airflow sensor comprises a base, a vibrating electrode, and a fixed electrode in a stacked arrangement, wherein the base has a back cavity passing through in its thickness direction. it is intended that the fixed electrode of the air flow sensor is provided with a vent hole and the perimeter edge of the vibration sensitive area of the vibration electrode is provided with a pressure equalizing hole. In the thickness direction of the substrate, the pressure equalizing hole The projection overlaps with the projection of the vent hole, and the pressure equalizing hole, the vent hole and the gap layer channel jointly form an air release channel, which is conducive to the smooth diffusion of oil smoke entering the air flow sensor along the air release channel.

### RELATED APPLICATIONS

This application is a Paris Convention, which claims the benefit of priority of China Patent Application No. 202311252106.6 filed on Sep. 26, 2023. The contents of the above application is all incorporated by reference as if fully set forth herein in its entirety.

### FIELD AND BACKGROUND OF THE INVENTION

This present invention relates to an airflow sensor used in electronic equipment in an environment with fume or other pollutants, and more specifically to an airflow sensor and an airflow sensor packaging structure.

Devices manufactured based on Micro-Electro-Mechanical System (MEMS) are called MEMS devices. The device of the MEMS capacitive pressure sensor comprises a diaphragm and a backplane, and there is a gap between the diaphragm and the backplane. Changes in air pressure will cause the diaphragm to deform, and the capacitance between the diaphragm and the backplane to change, thereby converting it into an electrical signal output.

For airflow sensors used in electronic equipment in environments with fume or other pollutants, when the airflow sensor senses that the user inhales, the diaphragm of the airflow sensor deforms, reducing the air pressure on both sides of the diaphragm of the airflow sensor. It is converted into a change in the internal capacitance of the airflow sensor to output a signal, so that the airflow sensor can work as a switch to control the atomizer of the electronic cigarette.

### SUMMARY OF THE INVENTION

The present invention aims to solve at least one of the technical problems existing in the prior art and provide an airflow sensor and an airflow sensor packaging structure.

The purpose of the present invention is achieved by the following

### Technical Solutions

According to a first aspect of the present invention, an airflow sensor is provided. The airflow sensor comprises:
a substrate, a vibrating electrode, and a fixed electrode in a laminated arrangement, wherein the substrate has a back cavity passing through the substrate in the thickness direction thereof;
wherein, the vibrating electrode has a vibration-sensitive area, and a gap layer is provided between the vibration-sensitive area and the fixed electrode. The vibrating electrode and the fixed electrode form a variable capacitor. The fixed electrode includes an insulating layer and a conductive layer, wherein the conductive layer is fixedly connected to the insulating layer. The projection of the conductive layer covers the projection of the back cavity in the thickness direction of the substrate, and a vent hole is only provided on the insulating layer with no vent hole provided on the conductive layer;
one of more pressure equalizing holes are provided on the perimeter edge of the vibration sensitive area of the vibration electrode. The projection of the pressure equalizing hole overlaps the projection of the vent hole in the thickness direction of the substrate, wherein an air release channel is formed by the pressure equalizing hole, the vent hole and the gap layer channel together to establish a continuous flow path in the space outside the back cavity and the air flow sensor, and the air release channel is connected to the gap layer.

The airflow sensor and the airflow sensor packaging structure provided by the present invention are intended to facilitate the smooth diffusion of pollutants (e.g., fume) entering into the airflow sensor along the air release channel by providing vent holes on the fixed electrode of the airflow sensor, one of more pressure equalizing holes are provided on the perimeter edge of the vibration sensitive area of the vibration electrode, in the thickness direction of the substrate, the projection of the pressure equalizing hole overlaps the projection of the vent hole, the pressure equalizing hole, the vent hole and the gap layer channel form an air release channel together. Then, in the non-working state, the pressure of the side surface of the vibrating electrode facing the back cavity and the side surface of the vibrating electrode away from the back cavity are equalized to prevent the ASIC (Application Specific Integrated Circuit) connected to the airflow sensor from detecting the signal, thereby causing other components to false trigger. It solves the problem that the holes in the PCB or the shell of electronic equipment containing fume are blocked by the cigarette oil, causing the vibrating electrode to deform under pressure and causing the capacitance to change, thereby causing the electronic equipment to be used in an environment with oil fume or other pollutants to generate the action of automatic triggering.

Further, in the embodiment of the present invention, because the vent holes are only provided on the insulating layer of the fixed electrode, the entire area of the conductive layer on the fixed electrode can be used as an effective area, thereby without changing the volume of the airflow sensor itself, the size of the variable capacitance of the airflow sensor is increased, thereby the detection sensitivity and performance of the airflow sensor are modified.

Further, contaminants entering from the pressure equalizing holes can be prevented from diffusing into the gap layer between the vibrating electrode and the fixed electrode, thereby the failure rate of the product is reduced.

### BRIEF DESCRIPTION OF THE SEVERAL VIEWS OF THE DRAWING(S)

To describe technical solutions in embodiments of this application more clearly, the following briefly introduces the accompanying drawings for describing the embodiments. It is clear that the accompanying drawings in the following descriptions show merely some embodiments of this application, and a person skilled in the art may still derive other drawings from these accompanying drawings without creative efforts.

FIG. 1A is a cross-sectional view from the front direction of the airflow sensor, according to an embodiment of the present invention;

FIG. 1B is a top view of the airflow sensor, according to the embodiment in FIG. 1A;

FIG. 2 is a cross-sectional view from the front direction of the airflow sensor, according to another embodiment of the present invention;

FIG. 3A is a cross-sectional view from the front direction of the airflow sensor, according to another embodiment of the present invention;

FIG. 3B is a top view of the airflow sensor, according to the embodiment in FIG. 3A;

FIG. 3C is a top view of the second support body in the airflow sensor, according to the embodiment in FIG. 3A;

FIG. 4 is an enlarged structural diagram of part A in FIG. 2;

FIG. 5 is a schematic structural diagram of the first barrier structure and the second barrier structure, according to another embodiment applied at part A in FIG. 2;

FIG. 6 is a schematic structural diagram of the first barrier structure and the second barrier structure, according to another embodiment applied at part A in FIG. 2;

FIG. 7 is a cross-sectional view from the front direction of the airflow sensor, according to another embodiment of the present invention;

FIG. 8 is a cross-sectional view from the front direction of the airflow sensor packaging structure, according to an embodiment of the present invention.

### DESCRIPTION OF SPECIFIC EMBODIMENTS OF THE INVENTION

The above description is only an overview of the technical solution of the present invention, in order to be able to more clearly understand the technical means of the present invention, and can be implemented in accordance with the contents of the specification, and in order to make the above and other purposes, features and advantages of the present invention can be more obvious and easy to understand, the following specially cites some embodiments and with the accompanying drawings, the following is described in detail.

In the description of the present invention, it should be noted that unless otherwise specified and limited, terms such as “set,” “connect,” and “attach” should be broadly interpreted. For example, it can be a fixed connection or a detachable connection, or even an integral connection. It can be a mechanical connection, an electrical connection, or a communicative connection. It can be directly connected or indirectly connected through an intermediate medium. It can refer to either internal communication between two components or the interaction between the two components. Ordinary technicians in this field can understand the specific meanings of the above-mentioned terms in the present invention based on specific circumstances.

At least one embodiment of this application provide an airflow sensor. The airflow senor comprises:
a substrate 10, a vibrating electrode 30, and a fixed electrode 50 in a laminated arrangement, wherein the substrate 10 has a back cavity 11 passing through the substrate 10 in the thickness direction thereof;
wherein, the vibrating electrode 30 has a vibration-sensitive area, and a gap layer 42 is provided between the vibration-sensitive area and the fixed electrode 50. The vibrating electrode 30 and the fixed electrode 50 form a variable capacitor. The fixed electrode 50 includes an insulating layer 501 and a conductive layer 601, wherein the conductive layer 601 is fixedly connected to the insulating layer 501. The projection of the conductive layer 601 covers the projection of the back cavity 11 in the thickness direction of the substrate 10, and a vent hole 51 is only provided on the insulating layer 501 with no vent hole 51 provided on the conductive layer 601;
one of more pressure equalizing holes 31 are provided on the perimeter edge of the vibration sensitive area of the vibration electrode. The projection of the pressure equalizing hole 31 overlaps the projection of the vent hole 51 in the thickness direction of the substrate 10, wherein an air release channel is formed by the pressure equalizing hole 31, the vent hole 51 and a gap layer 42 channel 41 together to establish a continuous flow path in the space outside the back cavity 11 and the air flow sensor, and the air release channel is connected to the gap layer 42.

It can be seen from the above, the embodiment of the present application establishes a continuous flow path in the space between the back cavity 11 and the airflow sensor 2 by providing vent holes 51 on the fixed electrode 50 of the airflow sensor 2, one of more pressure equalizing holes 31 are provided on the perimeter edge of the vibration sensitive area of the vibration electrode, in the thickness direction of the substrate 10, the projection of the pressure equalizing hole 31 overlaps the projection of the vent hole 51, the pressure equalizing hole 31, the vent hole 51 and the gap layer 42 channel 41 form an air release channel together. Then, in the non-working state, the pressure of the side surface of the vibrating electrode 30 facing the back cavity 11 and the side surface of the vibrating electrode 30 away from the back cavity 11 are equalized to prevent the ASIC connected to the airflow sensor 2 from detecting the signal, thereby causing other components to false trigger. It solves the problem that the holes in the PCB or the shell of electronic equipment containing fume are blocked by the cigarette oil, causing the vibrating electrode 30 to deform under pressure and causing the capacitance to change, thereby causing the electronic equipment to be used in an environment with fume or other pollutants to generate the action of automatic triggering.

### Embodiment One

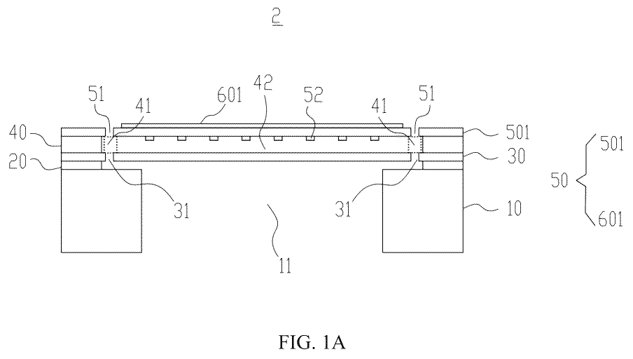

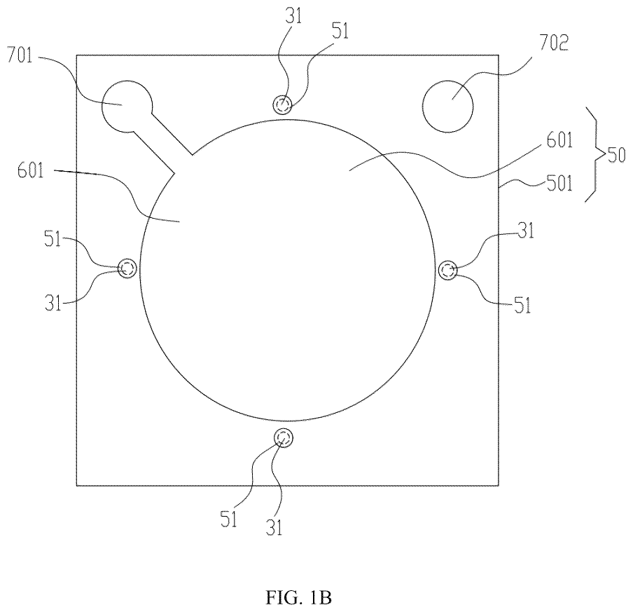

FIG. 1A is a cross-sectional view from the front direction of the airflow sensor 2, according to an embodiment of the present invention, FIG. 1B is a top view of the airflow sensor 2, according to the embodiment in FIG. 1A.

As shown in FIGS. 1A and 1B, the airflow sensor 2 comprise a substrate 10, a vibrating electrode 30, and a fixed electrode 50 in a stacked arrangement, wherein the substrate 10 has a back cavity 11 passing through in its thickness direction;
wherein, the vibrating electrode 30 has a vibration-sensitive area, and a gap layer 42 is provided between the vibration-sensitive area and the fixed electrode 50. The vibrating electrode 30 and the fixed electrode 50 form a variable capacitance. The fixed electrode 50 includes an insulating layer 501 and a conductive layer 601, wherein the conductive layer 601 is fixedly connected to the insulating layer 501. In the thickness direction of the substrate 10, the projection of the conductive layer 601 covers the projection of the back cavity 11. There is no vent hole 51 on the conductive layer 601, and the vent holes 51 are only provided on the insulating layer 501;
one of more pressure equalizing holes 31 are provided on the perimeter edge of the vibration sensitive area of the vibration electrode. The projection of the pressure equalizing hole 31 overlaps the projection of the vent hole 51 in the thickness direction of the substrate 10, wherein an air release channel is formed by the pressure equalizing hole 31, the vent hole 51 and a gap layer 42 channel 41 together to establish a continuous flow path in the space outside the back cavity 11 and the air flow sensor, and the air release channel is connected to the gap layer 42.

In the embodiment of the present application, it is intended that the fixed electrode 50 of the air flow sensor is provided with a vent hole 51 and the perimeter edge of the vibration sensitive area of the vibration electrode is provided with a pressure equalizing hole 31. In the thickness direction of the baseplate 3, the pressure equalizing hole 31 The projection overlaps with the projection of the vent hole 51, and the pressure equalizing hole 31, the vent hole 51 and the gap layer 42 channel 41 jointly form an air release channel, which is conducive to the smooth diffusion of fume entering the air flow sensor along the air release channel. Then, in the non-working state, the pressure of the side surface of the vibrating electrode 30 facing the back cavity 11 and the side surface of the vibrating electrode 30 away from the back cavity 11 are equalized to prevent the ASIC connected to the airflow sensor 2 from detecting the signal, thereby causing other components to false trigger. It solves the problem that the holes in the PCB or the shell of electronic equipment containing fume are blocked by the cigarette oil, causing the vibrating electrode 30 to deform under pressure and causing the capacitance to change, thereby causing the electronic equipment to be used in an environment with fume or other pollutants to generate the action of automatic triggering.

Further, in the embodiment of the present invention, because the vent holes 51 are only provided on the insulating layer 501 of the fixed electrode 50, the entire area of the conductive layer 601 on the fixed electrode 50 can be used as an effective area, thereby without changing the volume of the airflow sensor 2 itself, the size of the variable capacitance of the airflow sensor 2 is increased, thereby the detection sensitivity and performance of the airflow sensor 2 are modified.

Further, a first support body 20 is formed between the vibrating electrode 30 and the substrate 10 to connect a portion of the vibrating electrode 30 with a portion of the substrate 10, and a second support body 40 is formed between the fixed electrode 50 and the vibrating electrode 30 to connect a portion of the fixed electrode 50 with a portion of the vibrating electrode 30. The vent hole 51 on the fixed electrode 50 is distributed at the edge close to the second support body 40. The second support body 40 to reduce the probability that the airflow containing pollutants (e.g. fume, etc.) discharged to the space outside the airflow sensor 2 through the air release channel re-diffracted into the gap through the vent holes 51, thereby the service life of the product is increase.

For example, in some embodiments, both the first support body 20 and the second support body 40 are insulating support bodies, which may be, for example, silicon oxide or silicon nitride or the like. The thickness of the first support body 20 and the second support body 40 is between 2 and 3 μm, for example, around 2.5 μm. Under this condition, the vibrating electrode 30 and the fixed electrode 50 are opposed to each other and arranged at an insulating distance, so that an oscillation cavity for the vibrating electrode 30 to vibrate is formed between the fixed electrode 50 and the vibrating electrode 30, that is, a gap layer 42 as shown in FIG. 1A is formed.

For example, in this embodiment, the first support body 20 is located at the edge of the substrate 10 to support the vibrating electrode 30, so that the vibrating electrode 30 is suspended above the back cavity 11. Specifically, the vibrating electrode 30 comprises a vibration-sensitive area and a support area, wherein the support area elevates the vibrating electrode 30 above the back cavity 11 through the first support body 20. The second support body 40 is located at the edge of the vibrating electrode 30, so that the fixed electrode 50 is suspended above the vibrating electrode 30 and is insulated from the vibrating electrode 30. It should be noted that the vibrating electrode 30 in this embodiment is a planar membrane structure located directly above the back cavity 11. Generally, when subjected to external force, the vibrating electrode 30 deforms in an outward direction along the geometric center of the vibrating electrode 30, the deformation amount of the vibrating electrode 30 (the amplitude of the deformation of the vibrating electrode 30) decreases sequentially.

It should be noted that in the manufacturing process of an airflow sensor 2, there are usually thousands of release holes on the fixed electrode 50, and these thousands of release holes are evenly distributed on the fixed electrode 50 for use, therefore the sacrificial layer located between the fixed electrode 50 and the vibrating electrode 30 is removed by solution releasing method. In some embodiments, after the sacrificial layer located between the fixed electrode 50 and the vibration electrode is released to form a gap layer 42, the above-mentioned release holes need to be closed. Then, at least one vent hole 51 is etched on the insulating layer 501 on the edge of the fixed electrode 50 close to the second support body 40, wherein, the vent hole 51 passes through the insulating layer 501 in the thickness direction, so that the gap layer 42 is connected to the space outside the airflow sensor 2, thus the air pressure balance is achieved.

Further, the number of vent holes 51 on the fixed electrode 50 is less than or equal to 50, for example, 20, 30, 40 or 50.

It should be understood that in some embodiments, the fewer the number of vent holes 51, the better. In this case, contaminants (e.g. cigarette oil, etc.) will not diffuse (invade) into the gap layer 42 again, thereby perfectly solving the problem of film suction problems caused by contaminants (e.g., cigarette oil, etc.) between the vibrating electrode 30 and the fixed electrode 50, as well as the resulting problems of false triggering and short circuit.

For example, in this embodiment, the airflow sensor 2 further comprises a first soldering pad 701 and a second soldering pad 702. The first soldering pad 701 is electrically connected to the conductive layer 601 of the fixed electrode 50 and is used to transmit electrical signals of the conductive layer 601. The second pad is electrically connected to the vibrating electrode 30 and used to transmit the electrical signal of the vibrating electrode 30.

Further, in order to prevent the problem of adhesion caused by the film suction between the fixed electrode 50 and the vibrating electrode 30, an anti-adhesion structure 52 is provided on the side surface of the fixed electrode 50 facing the vibrating electrode 30, so that the adhesion caused by the film suction between the fixed electrode 50 and the vibrating electrode 30 is prevented.

Optionally, the anti-adhesion structure 52 is integrally formed with the insulating layer 501 on the fixed electrode 50.

### Embodiment Two

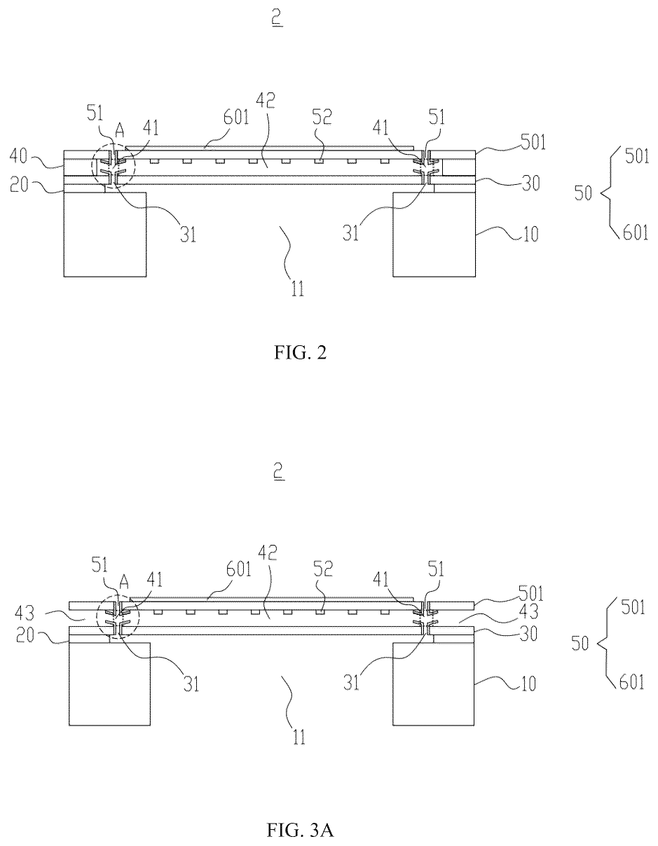

FIG. 2 is a cross-sectional view from the front direction of the airflow sensor 2, according to another embodiment of the present invention;
For example, as shown in FIG. 2, in order to minimize the entry of fume into the gap layer 42 through the gap layer 42 channel 41, in this embodiment, the airflow sensor 2 further comprises a first barrier structure 710 and a second barrier structure 720. The first barrier structure 710 comprises a first main body 711 and a first annular baffle 712 integrally connected to a side of the first main body 711, the first main body 711 is embedded in the vent hole 51, the first annular baffle 712 is disposed around the first main body 711. The second barrier structure 720 comprises a second main body 721 and a second annular baffle 722 integrally connected to a side of the second main body 721, the second main body 721 is embedded in the pressure equalizing hole 31, the second annular baffle 722 is disposed around the second main body 721; wherein, the first annular baffle 712 and the second annular baffle 722 are both located in the gap between the fixed electrode 50 and the vibrating electrode 30.

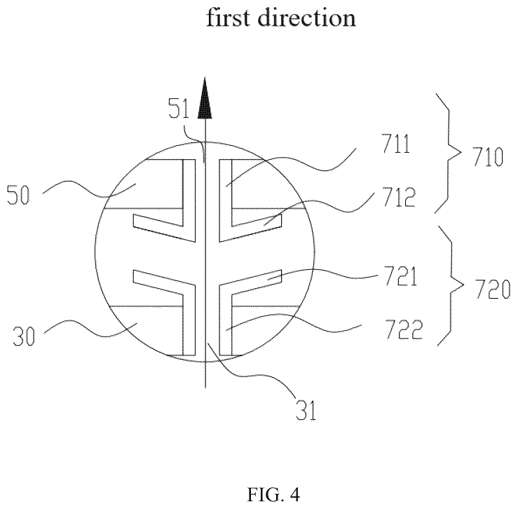

FIG. 4 is an enlarged structural diagram of part A in FIG. 2;
As shown in FIG. 4, in some embodiments, both the first annular baffle 712 and the second annular baffle 722 extend toward the fixed electrode 50.

For example, along a direction perpendicular to the plane in which the substrate 10 is located, the cross-section of the first annular baffle 712 forms an acute angle with the first direction, and the cross-section of the second annular baffle 722 forms an acute angle with the first direction; wherein, the first direction is the direction pointing to the vent hole51 from the pressure equalizing hole 31.

Considering that the cigarette oil is an extremely viscous substance, when the first annular baffle 712 and the second annular baffle 722 are designed to be tilted or cocked in the direction of the fixed electrode 50, it will lead to an increase in the diffusion resistance of the fume, the cigarette oil will preferentially adhere to the side walls of the first annular baffle 712 and the second annular baffle 722, and will not diffuse inside the gap layer 42, thereby effectively blocking the diffusion of the fume. If there is fume running in, the cigarette oil will accumulate on the side wall of the first annular baffle 712, and then the cigarette oil will flow down along the side wall of the first annular baffle 712 under the influence of gravity, just to the position of the intermediate gap layer 42 channel 41. When there is a relatively large amount of cigarette oil accumulating, the cigarette oil will fall down directly from the gap layer 42 channel 41, meanwhile the side wall of the second annular baffle 722 is tilted or cocked in the direction of the fixed electrode 50, so that the second barrier structure 720 is able to form a funnel-like structure to catch the cigarette oil leaking down from the side wall of the first annular baffle 712, and cigarette oil will be automatically recycled or collected along the inner wall of the second barrier structure 720.

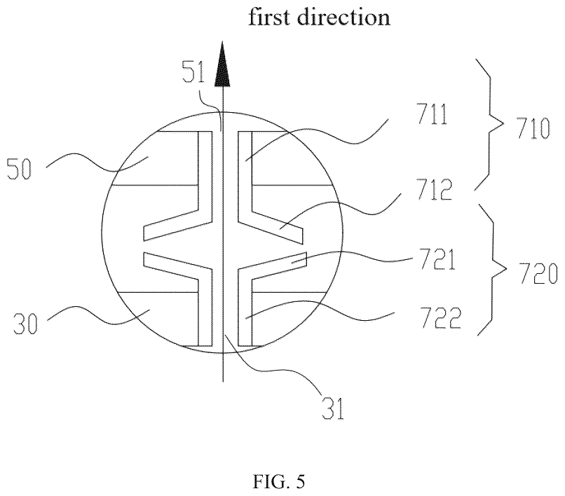

FIG. 5 is a schematic structural diagram of the first barrier structure 710 and the second barrier structure 720, according to another embodiment applied at part A in FIG. 2;
As shown in FIG. 5, in some embodiments, the first annular baffle 712 extends toward the vibrating electrode 30; the second annular baffle 722 extends toward the fixed electrode 50; the end of the first annular baffle 712 away from the first main body 711 and the end of the second annular baffle 722 away from the second main body 721 are opposite and not connected. Thereby, a gap is left between the first barrier structure 710 and the second barrier structure 720, allowing the gap layer 42 to be connected to the space beyond the airflow sensor 2 to achieve air pressure equilibrium.

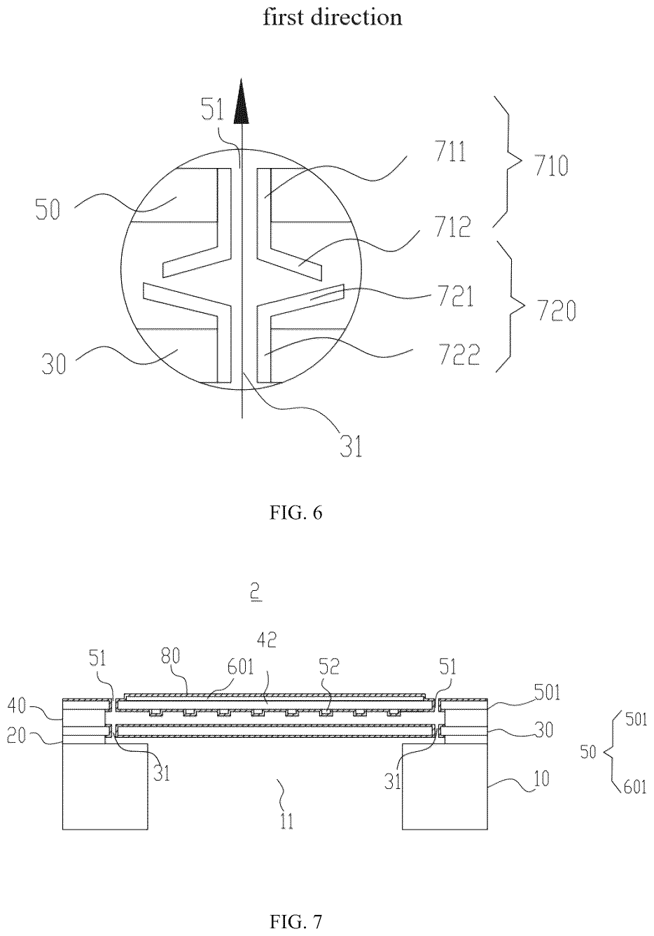

FIG. 6 is a schematic structural diagram of the first barrier structure 710 and the second barrier structure 720, according to another embodiment applied at part A in FIG. 2;
Further, in order to prevent accumulated cigarette oil from entering into the gap layer 42 through the above-mentioned gap, as shown in FIG. 5, in the thickness direction of the substrate 10, the projection of the first annular baffle 712 on the substrate 10 lies within the projection of the second annular baffle 722 on the substrate 10. That is, the cross-sectional length of the second annular baffle 722 in the second barrier structure 720 is relatively longer, so as to catch all of the cigarette oil leaking from the side walls of the first annular baffle 712, and automatically recycle or collect the cigarette oil along the inner wall of the second barrier structure 720.

For example, in some embodiments, the material of both the first barrier structure 710 and the second barrier structure 720 is SiNx.

### Embodiment Three

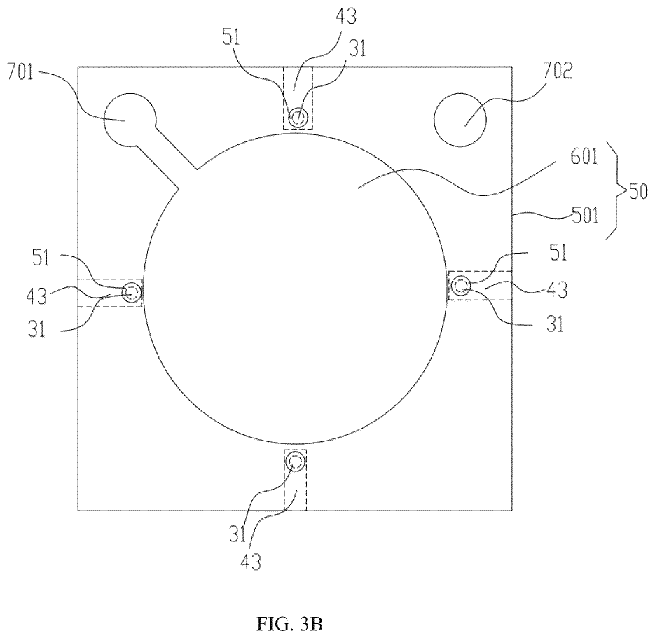

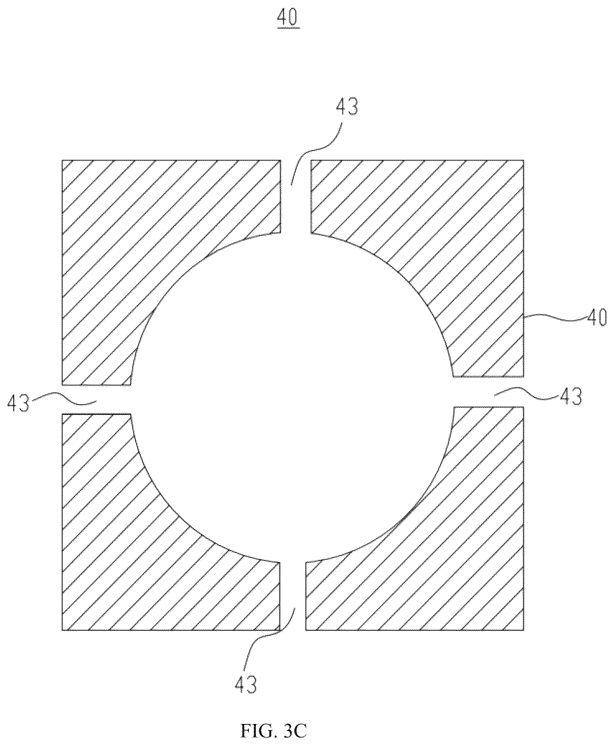

FIG. 3A is a cross-sectional view from the front direction of the airflow sensor 2, according to another embodiment of the present invention. FIG. 3B is a top view of the airflow sensor 2, according to the embodiment in FIG. 3A. FIG. 3C is a top view of the second support body 40 in the airflow sensor 2, according to the embodiment in FIG. 3A.

As shown in FIG. 3A, FIG. 3B, and FIG. 3C, for example, the difference between FIG. 3A and FIG. 2 is that: in this embodiment, the airflow sensor 2 comprises a pressure equalizing channel 43, wherein the pressure equalizing channel 43 is disposed through the gap between the fixed electrode 50 and the vibrating electrode 30, and is connected with the pressure equalizing hole 31 to establish a continuous flow path in the space outside the back cavity 11 and the air flow sensor. Then, in the non-working state, the pressure of the side surface of the vibrating electrode 30 facing the back cavity 11 and the side surface of the vibrating electrode 30 away from the back cavity 11 are equalized to prevent the ASIC connected to the airflow sensor 2 from detecting the signal, thereby causing other components to false trigger.

Specifically, in this embodiment, the air outlet of the pressure equalizing channel 43 is located at the gap between the fixed electrode 50 and the vibrating electrode 30. Further, the flow direction of the gas containing contaminants (e.g., cigarette oil, etc.) discharged from the outlet of the pressure equalizing channel 43 is completely different from the opening direction of the vent holes 51, and furthermore, the probability of the gas containing contaminants (e.g., cigarette oil, etc.) being bypassed from the vent holes 51 on the fixed electrodes 50 to enter into the gap layer 42 is reduced, and the service life of the product is improved.

It should be understood that in the embodiment of the present invention, in a direction perpendicular to the thickness of the substrate 10, the pressure equalizing channel 43 passes through the second support body 40. Specifically, as shown in FIG. 3C, part of the second support body 40 at the junction between the vibrating electrode 30 and the fixed electrode 50 may be etched to form a notch, thereby forming a pressure equalizing channel 43.

Similar to the above-mentioned embodiment, in this embodiment, vent holes 51 are provided only on the insulating layer 501 of the fixed electrode 50, the number of vent holes 51 is less than or equal to 50, and distributed at the perimeter edge of the conductive layer 601 to reduce the probability of the gas containing contaminants (e.g., cigarette oil, etc.) from the space outside the airflow sensor 2 being bypassed from the vent holes 51 on the fixed electrodes 50 to enter into the gap layer 42 is reduced, and the service life of the product is improved. Differently, in this embodiment, a continuous flow path is mainly established in the space outside the back cavity 11 and the airflow sensor 2 through a pressure equalizing structure composed of pressure equalizing holes 31 and pressure equalizing channels 43 to quickly balance the air pressure.

### Embodiment Four

FIG. 7 is a cross-sectional view from the front direction of the airflow sensor 2, according to another embodiment of the present invention;
As shown in FIG. 7, for example, in some embodiments, what is different from the previous embodiment is that: the airflow sensor 2 comprises an oleophobic layer 80, wherein the oleophobic layer 80 is disposed on the surfaces of the vibrating electrode 30 and the fixed electrode 50 and covers the side walls of the pressure equalizing hole 31, the gap layer 42 channel 41 and the vent hole 51.

The oleophobic layer 80, for example, is a SAM material, so that there is a thin oleophobic layer 80 on all layers, and when contaminants (e.g., cigarette oil, etc.) enter into the interstitial layer, they will accumulate on the surface of the vibrating electrode 30 without causing the vibrating electrode 30 and the fixed electrode 50 to absorb, meanwhile, the airflow sensor 2 in the electronic cigarette will not fail during operation. Further, an oleophobic layer 80 may also be added to other structures. For example, a sidewall of the back cavity 11 of the substrate 10 is also coated with an oleophobic layer 80, to further minimize the occurrence of suction of the fixed electrodes 50 and the vibrating electrodes 30, thereby the failure rate of the product is reduced.

It should be understood that, when applied in embodiment three, the oleophobic layer 80 is provided on the surface of the sidewalls of the vibrating electrode 30 and the fixed electrode 50 as well as covering the sidewalls of the pressure equalizing hole 31, the gap layer 42 channel 41, the vent hole 51, and the side wall of the pressure equalizing channel 43. The details will not be repeated.

### Embodiment Five

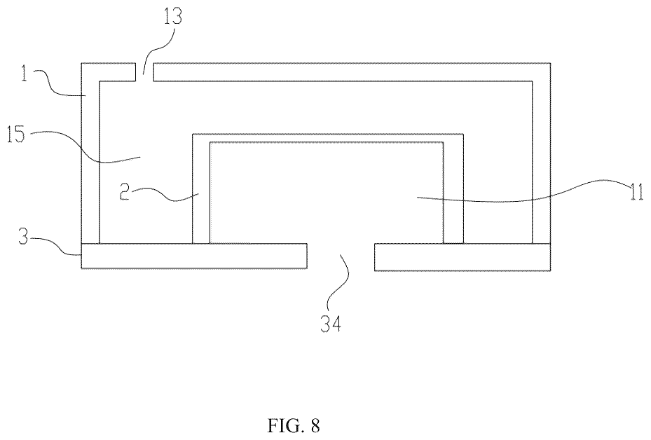

FIG. 8 is a cross-sectional view from the front direction of the airflow sensor 2 packaging structure, according to an embodiment of the present invention.

As shown in FIG. 8, according to another aspect of the present application, an air flow sensor packaging structure is also provided.

In some embodiments, the airflow sensor 2 packaging structure comprises a baseplate 3, a housing 1 and the above-mentioned airflow sensor 2; wherein, the baseplate 3 is fixedly connected to the housing 1 to form a cavity, the airflow sensor 2 is fixedly connected to a side surface of the baseplate 3 facing the housing 1 and is located in the cavity; a first through hole 34 is provided on the baseplate 3, a second through hole 13 is provided on the housing 1, the airflow sensor 2 covers the first through hole 34, and the air flow sensor separates the cavity into at least a back cavity 11 and a front cavity 15, the back cavity 11 is connected to the first through hole 34, so that the airflow containing fume in the internal channel of the electronic cigarette passes from the airflow sensor 2. The front cavity 15 is connected to the external environment via the second through hole 13, and the back cavity 11 is connected to the front cavity 15 via the air release channel, to sense the pressure difference between the external environment of the airflow sensor 2 packaging structure and a corresponding first through hole 34 of the airflow sensor 2 packaging structure.

In other embodiments, the airflow sensor 2 further comprises a pressure equalizing channel 43 as shown in Embodiment three. The pressure equalizing channel 43 is disposed through the gap between the fixed electrode 50 and the vibrating electrode 30, and the back cavity 11 is connected to the front cavity 15 via the pressure equalizing channel 43 and the pressure equalizing hole 31, thereby a continuous flow path in the space outside the back cavity 11 and the air flow sensor is established.

Using the airflow sensor 2 and airflow sensor 2 packaging structure provided in the embodiments of the present invention, it is intended that the fixed electrode 50 of the air flow sensor is provided with a vent hole 51 and the perimeter edge of the vibration sensitive area of the vibration electrode is provided with a pressure equalizing hole 31. In the thickness direction of the baseplate 3, the pressure equalizing hole 31 The projection overlaps with the projection of the vent hole 51, and the pressure equalizing hole 31, the vent hole 51 and the gap layer 42 channel 41 jointly form an air release channel, which is conducive to the smooth diffusion of oil smoke entering the air flow sensor along the air release channel. Then, in the non-working state, the pressure of the side surface of the vibrating electrode 30 facing the back cavity 11 and the side surface of the vibrating electrode 30 away from the back cavity 11 are equalized to prevent the ASIC connected to the airflow sensor 2 from detecting the signal, thereby causing other components to false trigger. It solves the problem that the holes in the PCB or the shell of electronic equipment containing fume are blocked by the cigarette oil, causing the vibrating electrode 30 to deform under pressure and causing the capacitance to change, thereby causing the electronic equipment to be used in an environment with fume or other pollutants to generate the action of automatic triggering.

Further, contaminants entering from the pressure equalizing holes 31 can be prevented from diffusing into the gap layer 42 between the vibrating electrode 30 and the fixed electrode 50, thereby the failure rate of the product is reduced.

Further, a first support body is formed between the vibrating electrode and the substrate to connect a portion of the vibrating electrode with a portion of the substrate, and a second support body is formed between the fixed electrode and the vibrating electrode to connect a portion of the fixed electrode with a portion of the vibrating electrode;
in a direction perpendicular to the thickness of the substrate, the vent hole is distributed at the edge close to the second support body.

Further, the number of the vent holes is less than or equal to 50.

Further, the airflow sensor comprises:
a first barrier structure, wherein the first barrier structure

comprises a first main body and a first annular baffle integrally connected to a side of the first main body, the first main body is embedded in the vent hole, the first annular baffle is disposed around the first main body; and
a second barrier structure, wherein the second barrier structure comprises a second main body and a second annular baffle integrally connected to a side of the second main body, the second main body is embedded in the pressure equalizing hole, the second annular baffle is disposed around the second main body;
wherein, the first annular baffle and the second annular baffle are both located in the gap between the fixed electrode and the vibrating electrode.

Further, both the first annular baffle and the second annular baffle extend toward the fixed electrode.

Further, along a direction perpendicular to the plane in which the substrate is located, the cross-section of the first annular baffle forms an acute angle with the first direction, and the cross-section of the second annular baffle forms an acute angle with the first direction;
wherein, the first direction is the direction pointing to the vent hole from the pressure equalizing hole.

Further, the first annular baffle extends toward the vibrating electrode;
the second annular baffle extends toward the fixed electrode;
the end of the first annular baffle away from the first main body and the end of the second annular baffle away from the second main body are opposite and not connected.

Further, in the thickness direction of the substrate, the projection of the first annular baffle on the substrate lies within the projection of the second annular baffle on the substrate.

Further, the material of both the first barrier structure and the second barrier structure is SiNx.

Further, the airflow sensor comprises a pressure equalizing channel, wherein the pressure equalizing channel is disposed through the gap between the fixed electrode and the vibrating electrode, and is connected with the pressure equalizing hole to establish a continuous flow path in the space outside the back cavity and the air flow sensor.

Further, the air outlet of the pressure equalizing channel is located at the gap between the fixed electrode and the vibrating electrode.

Further, an anti-adhesion structure is provided on a side surface of the fixed electrode facing the vibrating electrode.

Further, the anti-adhesion structure is integrally formed with the insulating layer on the fixed electrode.

Further, the airflow sensor comprises an oleophobic layer, wherein the oleophobic layer is disposed on the surfaces of the vibrating electrode and the fixed electrode and covers the side walls of the pressure equalizing hole, the gap layer channel and the vent hole.

According to a second aspect of the present invention, an airflow sensor packaging structure is provided. The airflow sensor packaging structure comprises a baseplate, a housing and the above-mentioned airflow sensors;
wherein, the baseplate is fixedly connected to the housing to form a cavity, the airflow sensor is fixedly connected to a side surface of the baseplate facing the housing and is located in the cavity;
wherein, a first through hole is provided on the baseplate, a second through hole is provided on the housing, the airflow sensor covers the first through hole, and the air flow sensor separates the cavity into at least a back cavity and a front cavity, the back cavity is connected to the first through hole, the front cavity is connected to the external environment via the second through hole, and the back cavity is connected to the front cavity via the air release channel.

Further, the airflow sensor is provided with a pressure equalizing channel, wherein the pressure equalizing channel is disposed through the gap between the fixed electrode and the vibrating electrode, and the back cavity is connected to the front cavity via the pressure equalizing channel and the pressure equalizing hole.

The above describes the embodiments of this application. However, these embodiments are only for illustrative purposes and not to limit the scope of the present application. The scope of this application is limited by the attached claims and their equivalents. Without departing from the scope of this application, technicians in the art may make various substitutions and modifications, all of which should fall within the scope of this application.

1. An airflow sensor, wherein the airflow sensor comprises:
a substrate, a vibrating electrode, and a fixed electrode in a laminated arrangement, wherein the substrate has a back cavity passing through the substrate in the thickness direction thereof;
wherein, the vibrating electrode has a vibration-sensitive area, and a gap layer is provided between the vibration-sensitive area and the fixed electrode, the vibrating electrode and the fixed electrode form a variable capacitor, the fixed electrode includes an insulating layer and a conductive layer, wherein the conductive layer is fixedly connected to the insulating layer, the projection of the conductive layer covers the projection of the back cavity in the thickness direction of the substrate, and a vent hole is only provided on the insulating layer with no vent hole provided on the conductive layer;
a pressure equalizing hole is provided on the perimeter edge of the vibration sensitive area of the vibration electrode, the projection of the pressure equalizing hole overlaps the projection of the vent hole in the thickness direction of the substrate, wherein an air release channel is formed by the pressure equalizing hole, the vent hole and a gap layer channel together to establish a continuous flow path in the space outside the back cavity and the air flow sensor, and the air release channel is connected to the gap layer.

2. The airflow sensor according to claim 1, wherein a first support body is formed between the vibrating electrode and the substrate to connect a portion of the vibrating electrode with a portion of the substrate, and a second support body is formed between the fixed electrode and the vibrating electrode to connect a portion of the fixed electrode with a portion of the vibrating electrode;
in a direction perpendicular to the thickness of the substrate, the vent hole is distributed at the edge close to the second support body.

3. The airflow sensor according to claim 2, wherein the number of the vent holes is less than or equal to 50.

4. The airflow sensor according to claim 2, wherein the airflow sensor further comprises:
a first barrier structure, wherein the first barrier structure comprises a first main body and a first annular baffle integrally connected to a side of the first main body, the first main body is embedded in the vent hole, the first annular baffle is disposed around the first main body; and
a second barrier structure, wherein the second barrier structure comprises a second main body and a second annular baffle integrally connected to a side of the second main body, the second main body is embedded in the pressure equalizing hole, the second annular baffle is disposed around the second main body;
wherein, the first annular baffle and the second annular baffle are both located in the gap between the fixed electrode and the vibrating electrode.

5. The airflow sensor according to claim 4, wherein both the first annular baffle and the second annular baffle extend toward the fixed electrode.

6. The airflow sensor according to claim 5, wherein along a direction perpendicular to the plane in which the substrate is located, the cross-section of the first annular baffle forms an acute angle with the first direction, and the cross-section of the second annular baffle forms an acute angle with the first direction;
wherein, the first direction is the direction pointing to the vent hole from the pressure equalizing hole.

7. The airflow sensor according to claim 4, wherein the first annular baffle extends toward the vibrating electrode;
the second annular baffle extends toward the fixed electrode;
the end of the first annular baffle away from the first main body and the end of the second annular baffle away from the second main body are opposite and not connected.

8. The airflow sensor according to claim 7, wherein, in the thickness direction of the substrate, the projection of the first annular baffle on the substrate lies within the projection of the second annular baffle on the substrate.

9. The airflow sensor according to claim 4, wherein the material of both the first barrier structure and the second barrier structure is SiNx.

10. The airflow sensor according to claim 4, wherein the airflow sensor comprises a pressure equalizing channel, wherein the pressure equalizing channel is disposed through the gap between the fixed electrode and the vibrating electrode, and is connected with the pressure equalizing hole to establish a continuous flow path in the space outside the back cavity and the air flow sensor.

11. The airflow sensor according to claim 10, wherein the air outlet of the pressure equalizing channel is located at the gap between the fixed electrode and the vibrating electrode.

12. The airflow sensor according to claim 1, wherein an anti-adhesion structure is provided on a side surface of the fixed electrode facing the vibrating electrode.

13. The airflow sensor according to claim 12, wherein the anti-adhesion structure is integrally formed with the insulating layer on the fixed electrode.

14. The airflow sensor according to claim 1, wherein the airflow sensor comprises an oleophobic layer,
wherein the oleophobic layer is disposed on the surfaces of the vibrating electrode and the fixed electrode and covers the side walls of the pressure equalizing hole, the gap layer channel and the vent hole.

15. An airflow sensor packaging structure, wherein the airflow sensor packaging structure comprises a baseplate, a housing and the airflow sensor according to claim 1;
wherein, the baseplate is fixedly connected to the housing to form a cavity, the airflow sensor is fixedly connected to a side surface of the baseplate facing the housing and is located in the cavity;
wherein, a first through hole is provided on the baseplate, a second through hole is provided on the housing, the airflow sensor covers the first through hole, and the air flow sensor separates the cavity into at least a back cavity and a front cavity, the back cavity is connected to the first through hole, the front cavity is connected to the external environment via the second through hole, and the back cavity is connected to the front cavity via the air release channel.

16. The airflow sensor packaging structure according to claim 15, wherein the airflow sensor is provided with a pressure equalizing channel, wherein the pressure equalizing channel is disposed through the gap between the fixed electrode and the vibrating electrode, and the back cavity is connected to the front cavity via the pressure equalizing channel and the pressure equalizing hole.
